(19) United States
(12) Patent Application Publication
(10) Pub. No.: US 2010/0132932 A1
(43) Pub. Date: Jun. 3, 2010

(54) METHOD FOR PRODUCING A METALIZED COMPONENT, CORRESPONDING COMPONENT, AND A SUBSTRATE FOR SUPPORTING THE COMPONENT DURING METALIZATION

(75) Inventor: Claus Peter Kluge, Roslau (DE)

Correspondence Address: FULBRIGHT & JAWORSKI, LLP, 666 FIFTH AVE, NEW YORK, NY, 10103-3198, US

(73) Assignee: CERAMTEC AG, Plochingen (DE)

(21) Appl. No.: 12/596,895

(22) PCT Filed: Apr. 17, 2008
(86) PCT No.: PCT/EP2008/054628

§ 371 Date: Oct. 21, 2009

(30) Foreign Application Priority Data
Apr. 24, 2007 (DE) 10 2007 019 630.1

(51) Int. Cl. H01L 23/373; B05D 3/02; B05C 13/00; B32B 18/00; B32B 15/04; F28F 7/00

(52) U.S. Cl. 165/185; 427/372.2; 118/500; 428/450; 428/472; 428/472.2; 428/469; 428/457

(57) ABSTRACT

Components having ceramic bases provided with a metalized structure on at least two opposite and/or juxtaposed faces at the same time, wherein metal in the form of pastes, films or sheets is provided for metallization and is applied to the surfaces of the ceramic base to be provided with a metalized structure.

The invention relates to a method for producing at least one component having a ceramics body which is covered, in at least one region of its surface, with a metallic coating, to a component produced by that method, and to a support for supporting the component during metallisation.

A method for producing copper/ceramics substrates in the form of sheets which are metallised on both sides is known from DE 10 2004 056 879 A1. In the direct copper bonding method, at least one of the metal layers of the ceramics body to be metallised rests on a ceramics separation layer of a support on which the components are stacked.

The object of the invention is to provide a method by which at least one body of a component of ceramics can be metallised on at least two opposing and/or adjacent sides simultaneously.

The object is achieved according to the method by means of the characterising features of claim 1, according to the device by means of the characterising features of claim 32, and by a component according to claim 46. Advantageous embodiments of the invention are described in the dependent claims.

In the method according to the invention for producing at least one component having a ceramics body which is to be covered with a metallic coating on at least two opposing and/or adjacent sides and wherein the ceramics body is spatially structured, the metal provided for the metallisation is applied in the form of pastes or films or sheets to the surfaces of the ceramics body that are to be metallised.

Before the metal is joined to the ceramics material, the components are placed on supports. The support bodies of the supports are covered with a separation layer at least on those surfaces that rest on the surfaces of the at least one component that are to be metallised. The method allows at least two opposing and/or adjacent surfaces of a ceramics body that is spatially structured to be metallised simultaneously.

The component and the support form a stack. For the simultaneous metallisation of a plurality of ceramics bodies, a plurality of stacks can be placed on one another to form a stack arrangement. A stack arrangement comprises at least two stacks. A support having a separation layer on both sides is inserted as a separation plate between the successive ceramics bodies in the stack arrangement, so that the separation layers of the support and the surfaces of the ceramics bodies that are covered with the metallic coating rest on one another.

Once the stacks have been placed on one another, a thermal method of metallisation is carried out. The preferred methods are the direct copper bonding method (DCB method) or the active metal brazing method (AMB method). After the metallisation, the components are removed from the supports.

The components are supported using supports whose support bodies have been produced from mullite, ZrO₂, Al₂O₃, AlN, Si₃N₄, SiC or from a mixture of at least two of the above-mentioned components. The supports have high heat resistance and are sufficiently stable that even stacking with a plurality of components is possible.

The components can also be supported using supports whose support bodies have been produced from a metal having high temperature stability, such as alloyed steel, molybdenum, titanium, tungsten or a mixture or alloy of at least two of the above-mentioned components. In this case too, the supports have high heat resistance and are sufficiently stable that even stacking with a plurality of components is possible.

The separation layer on the support bodies is produced as a porous layer of mullite, Al₂O₃, TiO₂, ZrO₂, MgO, CaO, CaCO₃ or mixtures of at least two of the mentioned materials, or of materials in which those components are used in production.

The separation layer is applied to the support body in a thickness of ≦20 mm and with a porosity (ratio of pore volume to solids volume) of ≦10%. The mentioned materials advantageously do not bond to the metals provided for the metallisation. The thickness of the layer and the porosity ensure that the layer does not tear or flake when exposed to heat.

The support body is produced in a thickness of from 0.2 mm to 30 mm. Production is carried out in accordance with the size and weight of the components, so that stability is ensured, in particular when a plurality of components is stacked.

The use of a support in which the deviations from an ideal flat surface are less than 0.4% of the support length and/or less than 0.2% of the support width prevents the surface of the metallic coating from becoming uneven or the metallic coating from distorting.

In order to form the separation layer, the surface of at least one side of the support body of the support is coated with a composition which contains at least one material of the separation layer in powder form in a liquid or aqueous matrix. After application of the coating that forms the separation layer, it is heated to a temperature higher than 100≦C for drying and/or in order to expel a binder.

The coating that forms the separation layer, i.e. the support provided with that coating, is heated to a temperature higher than 150≦C but lower than the sintering temperature of the material of the separation layer.

The separation layer is formed from the powdered material having a particle size of ≦70≦m. It is thereby ensured that the surface of the metallic coating is correspondingly smooth.

The coefficient of thermal expansion of the material of the support body can be chosen to be the same as or different from the coefficient of thermal expansion of the components. The material of the support body can have a coefficient of thermal expansion which differs from the coefficient of thermal expansion of the component with a metallic coating and can be chosen to be about 10% greater or less than the coefficient of thermal expansion of the ceramics material of the supported component.

The material of the support body should have a coefficient of thermal expansion of the order of magnitude of about 6.7×10⁻⁶/K.

The metallic coating can consist, for example, of tungsten, silver, gold, copper, platinum, palladium, nickel, aluminium or steel of pure or industrial grade, or of mixtures of at least two different metals. The metallic coating can also consist, for example, additionally or solely, of reactive solders, soft solders or hard solders.

The metallisation is advantageously carried out with copper sheets or copper films by the known DCB method.

On the upper side of at least one stack there can be placed a weighting body, the body of which can consist of the material of the support, the body being provided with a separation layer on the surface that rests on the metallic coating. As a result, in particular in a stack arrangement comprising a plurality of superposed stacks, such a pressure is exerted on the sheets or films provided for the metallisation that they are fully in contact with the surfaces of the ceramics bodies that are to be metallised and thus no defects occur in the metallisation.

In order to form a stack arrangement, the stacks can be placed one above the other and spacers can be positioned between the supports. Any desired number of stacks can thus be placed one above the other.

The structural form of the supports further allows different arrangements of the stacks to be provided and even enables the stacks within a stack arrangement to be separated from one another.

In order to carry out the metallisation by different methods simultaneously, for example by the DCB and AMB method, at least two stacks can each be accommodated in a chamber that is delimited at least partially by a support. The chamber is closed by a plate positioned on the support in question or by another support. The spatial separation of the stacks allows different methods to be carried out in one stack arrangement simultaneously.

In the case of cup-, trough- or channel-shaped supports, a plurality of stacks can be stacked one above the other to form a stack arrangement, the lower side of one support resting on the side walls of the lower support and covering the cup, trough or channel with the component or components located therein. As a result, the supports advantageously at the same time form the reaction chamber in which the metallisation takes place.

Owing to the arrangement of the stacks and/or the structural form of the supports and their arrangement, the heat treatment and exposure to inert gases can be matched to each stack individually.

The surface of the support body and/or the separation layer on the support body can be structured over its entire surface or over part of its surface or in combinations thereof. The structuring can consist of spaced grooves or slots or channels, also in lattice form, by means of which the separation layer, the support surface, is divided into regions of small surface area. The support surface, and accordingly also contact with the separation layer, is thus reduced. The access of the gases for metallisation and the heating and cooling of the components can be influenced as a result.

The body of the component consists of a ceramics material which, in terms of its composition, can be matched to the required properties, for example insulation, partial discharge resistance and heat stability.

The ceramics material contains as the main component from 50.1 wt. % to 100 wt. % ZrO₂/HfO₂ or from 50.1 wt. % to 100 wt. % Al₂O₃ or from 50.1 wt. % to 100 wt. % AlN or from 50.1 wt. % to 100 wt. % Si₃N₄ or from 50.1 wt. % to 100 wt. % BeO, from 50.1 wt. % to 100 wt. % SiC or a combination of at least two of the main components in any desired combination within the indicated range, and as subsidiary component the elements Ca, Sr, Si, Mg, B, Y, Sc, Ce, Cu, Zn, Pb in at least one oxidation stage and/or compound in an amount of ≦49.9 wt. % individually or in any desired combination within the indicated range. The main components and the subsidiary components, with subtraction of an amount of impurities of ≦3 wt. %, can be combined with one another in any desired combination to give a total composition of 100 wt. %.

Materials of this composition are suitable for the production of components in particular owing to the achievable thermal capacity and the good metallising ability.

The layers of the metallic coating are applied in a thickness of from 0.05 mm to 2 mm, depending on the function of the metallising layer. The ratio of the thickness of the layers of the metallic coating to the height of the component can be less than two.

The layers of the metallic coating can also be applied in different thicknesses. For example, depending on the function of the layer of the metallic coating, it is possible to apply to one side of the ceramics body of the component a layer having a different thickness than that on the opposing and/or adjacent side.

The minimum dimensions of a component in a two-dimensional projection are at least greater than 80≦m×80≦m. The minimum height not in the two-dimensional projection is greater than 80 ≦m.

The body, consisting of ceramics, of the component is advantageously a heat sink. A heat sink is understood as being a body which carries electrical or electronic structural elements or circuits and is so formed that it is able to dissipate the heat formed in the structural elements or circuits so that there is no accumulation of heat which may damage the structural elements or circuits. The ceramics body is made of a material which is electrically non-conducting or virtually non-conducting and which has good heat conductivity.

The ceramics body is in one piece and has elements which dissipate or supply heat in order to protect the electronic structural elements or circuits. Preferably, the ceramics body is a plate and the elements are bores, channels, ribs and/or recesses to which a heating or cooling medium can be applied. The medium can be liquid or gaseous. The ceramics body with its cooling elements preferably consist of at least one ceramics component or a composite of different ceramics materials.

The invention is explained in greater detail by means of exemplary embodiments. In the drawings:

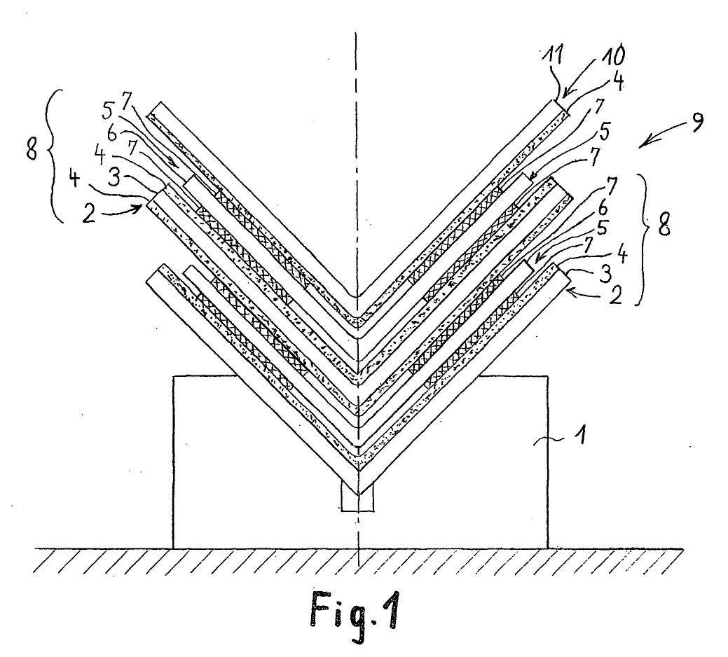

FIG. 1 shows a stack arrangement of two stacks and a weighting body,

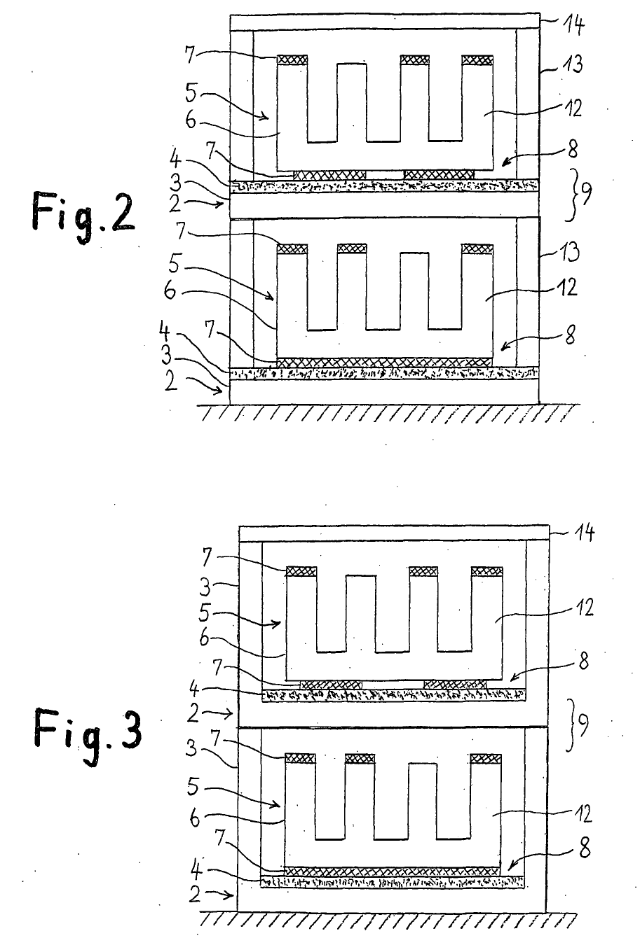

FIG. 2 shows a stack arrangement of two stacks with supports in plate form,

FIG. 3 shows a stack arrangement of two stacks with supports in channel form, and

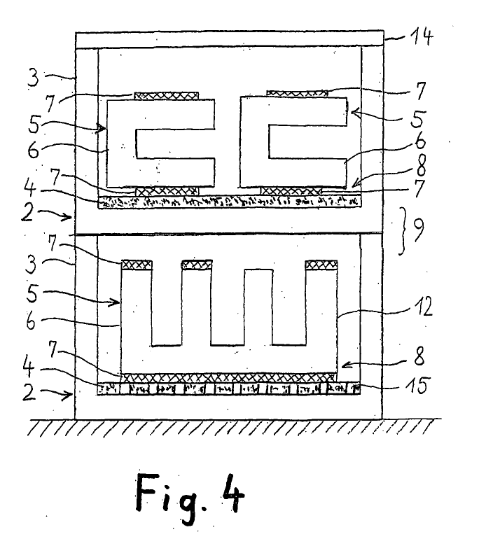

FIG. 4 shows a stack arrangement of two stacks with supports in channel form and differently shaped components.

FIG. 1 shows a stack arrangement in accordance with the invention. In a holding device 1 of an oven (not shown in detail here) for carrying out the metallisation there is first placed a support 2 which is provided on the surface of its support body 3 with a separation layer 4. The support 2 is angular so that it is able to accommodate an angular component 5, that is to say a spatially structured ceramics body 6, which is to be provided with metallic coatings 7 on its upper and lower side. The metallic coatings 7 are disposed flat and mutually symmetrically on the upper and lower side of each limb of the angular ceramics body 6.

The support 2 and the component 5 located thereon form a stack 8.

On the component 5 there is placed a further support 2, the support body 3 of which is covered with a separation layer 4 on both the upper side and the lower side. That support serves as a separation plate. As a separation plate, it separates two components stacked on one another. The subsequent component 5 has the same construction as the preceding component 5 and, together with its support 2, likewise forms a stack 8.

The two stacks 8 resting on one another form a stack arrangement 9.

On the uppermost stack 8 there rests a weighting body 10, the body 11 of which can consist of the material of the support. The body is provided with a separation layer 4 on the surface that rests on the metallic coating 7 of the component 5 located beneath it. The effect of the weighting body 10 is that the films or sheets provided for the metallisation are fully in contact with the surfaces of the ceramics bodies 6 that are to be metallised.

FIG. 2 shows a further embodiment of a stack arrangement which is provided for metallisation. Features that correspond with the preceding embodiment have been given the same reference numerals. In an oven (not shown in detail here) for carrying out the metallisation there is located a support 2, which in this case is in plate form. The support body 3 carries a separation layer 4 on its upper side. A component 5 having an E-shaped ceramics body 6, which represents a heat sink, rests on the support 2. The ceramics body 6 rests on the support with its flat side. That side bears a metallic coating 7 over its entire surface. Certain cooling ribs 12 of the ceramics body 6 also bear a metallic coating 7 on their end faces.

On the above-described stack 8 there is positioned a further stack 8 of identical construction. Spacers 13 placed on the lower support 2 carry the upper stack. The spacers 13 can be produced from the same ceramics material as the supports 2. The upper stack is covered by a plate 14. The two superposed stacks 8 form a stack arrangement 9.

As will be seen, the surfaces on which the ceramics body 6 of the upper stack 8 is metallised do not correspond with the surfaces of the metallic coating of the lower ceramics body. The stack arrangement allows ceramics bodies of the same shape to be metallised on different surfaces simultaneously.

In FIG. 3, the components 5 of the lower and upper stack 8 in the stack arrangement 9 that are to be metallised are identical with those of the corresponding stack according to the embodiment of FIG. 2. Only the shape of the supports 2 differs from that of the preceding embodiment. The supports 2 are in channel form, that is to say, instead of the spacers, the support itself, with its side walls and the base of the support arranged above it, forms the reaction chamber. The base of the support is covered with the separation layer 4.

The supports 2 and spacers 13, or supports in the form of, for example, a cup, a trough or a channel, delimit chambers in which the metallisation takes place. Such delimited chambers even make it possible for the parameters of the method that are necessary for the metallisation to be adjusted differently in each chamber.

Stack arrangements even allow components of different shapes to be metallised in one and the same operation. This is shown by means of the stack arrangement 9 of the embodiment according to FIG. 4. Here too, as in the embodiment of FIG. 3, the supports are in the form of channels. The lower stack 8 is comparable with the lower stack 8 according to FIG. 3. Unlike FIG. 3, however, the separation layer 4 in this case is structured, that is to say it is interrupted by spaced slots 15. As a result, the layer of the metallic coating 7 is not in contact with the separation layer 4 over its entire surface. In the stack 8 located above, the components 5 have a completely different shape. There are two components 5 in the support 2, the ceramics bodies 6 of which are U-shaped. The ceramics bodies 6 are in each case located with one limb on the separation layer 4 and are in each case provided with a metallic coating 7 on the outside of the limbs.

1. A method for producing at least one component having a ceramics body which is covered, in at least one region of its surface, with a metallic coating, wherein the ceramics body is spatially structured, wherein the metal provided for the metallization is applied in the form of pastes or films or sheets to the surfaces of the ceramics body that are to be metallized, wherein, before the metal is joined to the ceramics material, the at least one component is placed on a support and a stack is thus formed, wherein the support body of the support is provided beforehand with a separation layer at least on the surfaces that are to rest on the at least one component, and wherein, after the metallization, the at least one component is removed from the support.

2. A method according to claim 1, wherein, in the metallization of a plurality of components, the components are each placed on a support and stacks are thereby formed in each case, wherein the stacks are placed on one another in such a manner that a stack arrangement having at least two stacks is formed, and wherein the metallization of the components of the stack arrangement is then carried out.

3. A method according to claim 1, wherein the components are supported using supports having a support body that has been produced from mullite, ZrO₂, Al₂O₃, AlN, Si₃N₄, SiC or from a mixture of at least two of the above-mentioned components.

4. A method according to claim 1, wherein the components are supported using supports having a support body that has been produced from a metal having high temperature resistance, such as alloyed steel, molybdenum, titanium, tungsten, or from a mixture or alloy of at least two of the above-mentioned components.

5. A method according to claim 1, wherein the separation layer is produced on the supports as a porous layer of mullite, Al₂O₃, TiO₂, ZrO₂, MgO, CaO, CaCO₃ or mixtures of at least two of the mentioned materials, or of materials in which those components are used in production.

6. A method according to claim 1, wherein the separation layer is applied in a thickness of ≦20 mm.

7. A method according to claim 1, wherein the separation layer is produced with a porosity (ratio of pore volume to solids volume) of ≦10%.

8. A method according to claim 1, wherein the support body of the support is produced in a thickness of from 0.2 mm to 30 mm.

8. A method according to claim 1, characterized by the use of a support in which the deviations from an ideal flat surface are less than 0.4% of the support length or less than 0.2% of the support width.

10. A method according claim 1, wherein, in order to form the separation layer on the surface of the support, at least the surfaces of the support body that are to rest on a component are coated with a composition which contains at least one separation layer material in powder form in a liquid or aqueous matrix.

11. A method according to claim 1, wherein, after application of the coating that forms the separation layer, the coating is heated to a temperature higher than 100≦C for drying or in order to expel a binder.

12. A method according to claim 1, wherein the coating that forms the separation layer, or the support provided with that coating, is heated to a temperature higher than 150≦C but lower than the sintering temperature of the material of the separation layer.

13. A method according to claim 1, wherein the separation layer is formed by a powdered material having a particle size of ≦70≦m.

14. A method according to claim 1, wherein the coefficient of thermal expansion of the material of at least one support is chosen to be the same as or different from the coefficient of thermal expansion of at least one component.

15. A method according to claim 1, wherein the material that forms the support body of the support is produced with a coefficient of thermal expansion which differs from the coefficient of thermal expansion of the component with the metallic coating and is chosen to be about 10% greater or smaller than the coefficient of thermal expansion of the ceramics material of the supported component.

16. A method according to claim 1, wherein the material of the support body of the support is produced with a coefficient of thermal expansion of the order of magnitude of about 6.7×10⁻⁶/K.

17. A method according to claim 1, wherein the metallization is preferably carried out with metals from tungsten, silver, gold, copper, platinum, palladium, nickel, aluminum or steel of pure or industrial grade, or with mixtures of at least two different metals or, additionally or solely, with reactive solders, soft solders or hard solders.

18. A method according to claim 17, wherein the metallization is carried out with copper sheets or copper films according to the DCB method.

18. A method according to claim 1, wherein a support which acts as a separation plate and has a separation layer on both sides is inserted between the successive ceramics bodies in the stack arrangement so that the separation layers of the support and the surfaces to be metallized of the ceramics bodies with the applied metal rest on one another.

20. A method according to claim 1, wherein, in order to form a stack arrangement of superposed stacks, spacers are positioned between the supports.

21. A method according to claim 1, wherein at least one stack is accommodated in a chamber which is delimited at least partially by the support and is closed by a plate positioned on the stack arrangement.

22. A method according to claim 1, wherein the cup-, trough- or channel-shaped supports of a plurality of stacks are stacked one above the other to form a stack arrangement, the lower side of one support resting on the side walls of the lower support covering the cup, trough or channel with the component.

23. A method according to claim 1, wherein there is placed on the upper side of at least one stack a weighting body whose body can consist of the material of the support, the body being provided with a separation layer on the surface that rests on the metallic coating.

24. A method according to claim 1, wherein, in order to carry out the metallization by different methods simultaneously, at least two stacks are each accommodated in a chamber delimited at least partially by a support, the chamber being closed by a plate placed on the stack in question or by another support.

25. A method according to claim 1, wherein the surface of the support body or the separation layer on the support body is structured over its entire surface or over part of its surface or in combinations thereof.

26. A method according to claim 1, wherein the ceramics material is composed of a main component of from 50.1 wt. % to 100 wt. % ZrO₂/HfO₂ or from 50.1 wt. % to 100 wt. % Al₂O₃ or from 50.1 wt. % to 100 wt. % AlN or from 50.1 wt. % to 100 wt. % Si₃N₄ or from 50.1 wt. % to 100 wt. % BeO, from 50.1 wt. % to 100 wt. % SiC or of a combination of at least two of the main components in any desired combination within the indicated range, and of at least one subsidiary component from the elements Ca, Sr, Si, Mg, B, Y, Sc, Ce, Cu, Zn, Pb in at least one oxidation stage or compound in an amount of 49.9 wt. % individually or in any desired combination within the indicated range, and wherein the main components and the subsidiary components, with subtraction of an amount of impurities of ≦3 wt. %, are combined with one another in any desired combination to give a total composition of 100 wt. %.

27. A method according to claim 1, wherein the minimum dimensions of a component in a two-dimensional projection are at least greater than 80≦m×80≦m.

28. A method according to claim 1, wherein the minimum height not in the two-dimensional projection is greater than 80≦m.

28. A method according to claim 1, wherein the layers of the metallic coating in at least one stack are applied in a thickness of from 0.05 mm to 2 mm.

30. A method according to claim 1, wherein the ratio of the thickness of the layers of the metallic coating to the height of the component in at least one stack is less than two.

31. A method according to claim 1, wherein the layers of the metallic coating of at least one stack are applied in different thicknesses.

32. A support for use in the production of at least one component having a ceramics body which is covered on at least two opposing sides with a metallic coating, wherein the support is covered with a separation layer at least on one side of the support body on the surfaces that rest on the surfaces of the at least one component that are to be provided with the metallic coating, and wherein the component is spatially structured.

33. A support according to claim 32, wherein the material of the support body consists of mullite, ZrO₂, Al₂O₃, AlN, Si₃N₄, SiC or of a mixture of at least two of the above-mentioned components.

34. A support according to claim 32 or 33, wherein the separation layer on the support body consists of mullite, Al₂O₃, TiO₂, ZrO₂, MgO, CaO, CaCO₃ or mixtures of at least two different materials of the separation layer or materials in which those components are used in production.

35. A support according to claim 1, wherein the support body of the support has a thickness of from 0.2 mm to 30 mm.

36. A support according to claim 1, wherein the deviations from an ideal flat surface of a support are less than 0.4% of the support length or less than 0.2% of the support width.

37. A support according to claim 1, wherein the separation layer has a thickness of ≦20 mm.

38. A support according to claim 1, wherein the particles that form the separation layer have a size of ≦70≦m.

38. A support according to claim 1, wherein the separation layer has a porosity (ratio of pore volume to solids volume) of ≦10% throughout its entire thickness.

40. A support according to claim 1, wherein the separation layer has at least two regions of identical or different thicknesses.

41. A support according to claim 1, wherein, where the support body is cup-, trough- or channel-shaped, at least the base has a separation layer on the inside.

42. A support according to claim 1, wherein, where the support body is cup-, trough- or channel-shaped, the inside of the side walls or the inside or outside of the base have a separation layer.

43. A support according to claim 1, wherein the surface of the support body or the separation layer on the support body is structured over its entire surface or over part of its surface or in combinations thereof.

44. A support according to claim 1, wherein the material that forms the support body has a coefficient of thermal expansion which differs from the coefficient of thermal expansion of the component with the metallic coating and is about 10% greater or less than the coefficient of thermal expansion of the ceramics material of the component.

45. A support according to claim 1, wherein the material of the support body has a coefficient of thermal expansion of the order of magnitude of about 6.7×10⁻⁶/K.

46. A component having a ceramics body which is covered with a metallic coating in at least one region of its surface, wherein the ceramics body is spatially structured, wherein the ceramics material contains as the main component from 50.1 wt. % to 100 wt. % ZrO₂/HfO₂ or from 50.1 wt. % to 100 wt. % Al₂O₃ or from 50.1 wt. % to 100 wt. % AlN or from 50.1 wt. % to 100 wt. % Si₃N₄ or from 50.1 wt. % to 100 wt. % BeO, from 50.1 wt. % to 100 wt. % SiC or a combination of at least two of the main components in any desired combination within the indicated range, and as subsidiary component the elements Ca, Sr, Si, Mg, B, Y, Sc, Ce, Cu, Zn, Pb in at least one oxidation stage or compound in an amount of ≦49.9 wt. % individually or in any desired combination within the indicated range, and wherein the main components and the subsidiary components, with subtraction of an amount of impurities of ≦3 wt. %, are combined with one another in any desired combination to give a total composition of 100 wt. %.

47. Component according to claim 46, wherein the ceramics body provided with cooling ribs is in the form of a heat sink.
